(19) United States
(12) Patent Application Publication
(10) Pub. No.: US 2025/0223717 A1
(43) Pub. Date: Jul. 10, 2025

(54) COPPER PLATING ADDITIVE COMPOSITIONS, COPPER PLATING SOLUTIONS, AND USES THEREOF

(71) Applicant: JIANGYIN NANOPORE INNOVATIVE MATERIALS TECHNOLOGY LTD, Wuxi (CN)

(72) Inventors: Guochun LIU, Wuxi (CN); Xuefa LI, Wuxi (CN); Guoping ZHANG, Wuxi (CN)

(21) Appl. No.: 18/850,064

(22) PCT Filed: Mar. 23, 2023
(86) PCT No.: PCT/CN2023/083344

§ 371 Date: Sep. 24, 2024

(30) Foreign Application Priority Data
Mar. 25, 2022 (CN) 202210299212.9
Mar. 25, 2022 (CN) 202210299338.6
May 24, 2022 (WO) PCT/CN2022/094681
May 24, 2022 (WO) PCT/CN2022/094709

(51) Int. Cl. C25D 3/38; C25D 5/56

(52) U.S. Cl. CPC C25D 3/38; C25D 5/56

(57) ABSTRACT

Provided are a copper plating additive composition, a copper plating solution, and a copper brush plating method using the same. The copper plating additive composition includes 1,4-cyclohexanedione monoethylene acetal, potassium phthalimide, and an amino polyol compound.

### CROSS-REFERENCE TO RELATED APPLICATIONS

This application claims priority to and benefits of Chinese patent applications Nos. 2022102992129, and 2022102993386, filed Mar. 25, 2022, and International Application Nos. PCT/CN2022/094709, and PCT/CN2022 094681, filed May 24, 2022, all of which are incorporated herein by reference in their entiretics.

### TECHNICAL FIELD

The present disclosure relates to the technical field of copper plating, and in particular to copper plating additive compositions, copper plating solutions, and uses thereof.

### BACKGROUND

Brush electroplating (also known as metal pen plating, rapid plating, or brush plating) is a technological process for forming a metal coating by using an electrochemical method to discharge and crystallize metal ions on a surface of a cathode (workpiece) while using a plating pen impregnated with a plating solution as an anode.

The copper brush plating is mainly used in the fields requiring relatively high electrical conductivities such as electronics, electricity, and aerospace, etc., and especially has high practical values in local plating and coating repair. In operation, since the relative motion between the cathode and the anode is fast, a relatively higher current density (several times to dozens of times greater than the current density used in bath plating) can be used. In addition, the plating solution of the copper brush plating has a relatively high concentration of copper ion, permitting very high plating speed (such as 5 times to 10 times faster than that of the bath plating). In recent decades, scientists around the world have conducted in-depth and extensive researches on the cyanide-free copper plating technology, which has been industrialized and has achieved good social and economic effects. However, the cyanide-free copper brush plating still has some deficiencies, such as the unevenness and less bright appearance of the plating layer.

Moreover, there are generally two methods for double-sided copper plating on a plastic film (such as a polypropylene (PP) or polyethylene terephthalate (PET) film) with a thickness ranging from 3.2 μm to 12 μm: the magnetron sputtering in combination with the electroplating, and the evaporation deposition in combination with the electroplating. Both of the two methods have the problem of low yield. The main issues are the uneven thickness of the copper film formed by the magnetron sputtering or the evaporation deposition and the frequently occurred film perforation and film breakage caused by the copper electroplating burnt holes.

In addition, the copper film produced by the magnetron sputtering or the evaporation deposition is not thick enough, inducing an excessive sheet resistance of the film (usually about 2000 milliohms (mΩ)). Consequentially, the copper film has to be thickened in order to reduce the sheet resistance to less than 500 mΩ. The conventional method is to adopt acid copper electroplating, which can form a dense copper plating layer with a satisfied sheet resistance. However, at present, the greatest challenge is that the cathode roller in contact with the plastic film will be plated with copper in the process of copper electroplating, and the copper plated part of the cathode roller may easily puncture the plastic film, forming holes in the plastic film to be plated, which is unqualified. Meanwhile, the uniformity in thickness of the plating layer may be poor, the edge of the plating layer is easy to be burnt, and defects such as burnt holes, perforation, film breakage, etc. may occur in the plating layer, ultimately resulting in a low yield and low production efficiency. However, if the sheet resistance is greatly reduced in the magnetron sputtering or evaporation deposition process, the risk of perforation and burning holes in the plating layer will be greatly increased. In addition, the electroplating current of the subsequent acid copper electroplating cannot be relatively high, which greatly reduces the film thickness and induces the excessive sheet resistance, which hardly satisfies the final product requirement. On the contrary, if the electric current of the acid copper electroplating is too high, the possibility and degree of copper plating on the cathode roller will increase, resulting in the high possibility of the plastic film puncture or burning. Thus, both the magnetron sputtering in combination with the acid copper electroplating and the evaporation deposition in combination with the acid copper electroplating are complex and difficult to control, let alone controlling the yield of one-time processed final products.

In addition, the metallized plastic film can be brittle after the acid copper electroplating process, and is not suitable for multiple acid copper electroplating processes. After one time or at most two times of electroplating, the film is easy to be broken under drawing, which is unqualified and will scrap the entire film subjected to the previous processes, which is wasteful and has no economic value.

In view of the above, the current brush electroplating still has the deficiencies, such as the unevenness and less bright appearance of the plating layer. The copper brush plating on the plastic film still has many problems that are difficult to coordinate. There is a need in the industry for a high plating speed copper plating solution that can greatly improve the uniformity, brightness and saturation of the plating layer, as well as a copper brush plating process on a plastic film that can increase the thickness and uniformity of the copper plating layer, minimize puncturing the plastic film, satisfy the sheet resistance requirement for the film product, and provide good adhesion between copper plating layers.

### SUMMARY

The present disclosure provides a copper plating additive composition, a copper plating solution, and a copper brush plating process.

The first aspect of the present disclosure relates to a copper plating additive composition, comprising: 1,4-cyclohexanedione monoethylene acetal, potassium phthalimide, and an amino polyol compound.

In an embodiment, a mass ratio of 1,4-cyclohexanedione monoethylene acetal, potassium phthalimide, and the amino polyol compound is (0.6-1.0): (1.2-2.0): (1.8-3.0).

In an embodiment, the mass ratio of 1,4-cyclohexanedione monoethylene acetal, potassium phthalimide, and the amino polyol compound is (0.8-1.0): (1.5-2.0): (2.0-3.0).

In an embodiment, the amino polyol compound is 3-amino-1,2-propanediol.

The present disclosure also provides a copper plating solution, comprising the copper plating additive composition as described above.

In an embodiment, the copper plating solution further comprises water, copper sulfate (CuSO₄), sulfuric acid, and chloride ions. The chloride ion can be from compounds containing chloride ion that are soluble in water, such as hydrogen chloride.

In an embodiment, one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid, and
60 mg to 80 mg of chloride ions.

In an embodiment, the copper plating solution further comprises a brightener, a surfactant, and a levelling agent.

In an embodiment, the brightener is one or more selected from ethylene thiourea, benzimidazole, and fatty amine ethoxy sulfonate.

In an embodiment, the surfactant is one or more selected from sodium dodecyl sulfonate, and bis-(sodium sulfopropyl)-disulfide.

In an embodiment, the levelling agent is one or more selected from polyethylene glycol, 1,4-butynediol, and polyethyleneimine alkyl salt.

In an embodiment, one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid,
60 mg to 80 mg of chloride ions,
0.0002 mg to 0.0008 mg of the brightener,
0.05 mg to 0.1 mg of the surfactant, and
0.05 g to 0.1 g of the levelling agent.

In an embodiment, one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid,
60 mg to 80 mg of chloride ions,
0.0002 mg to 0.0008 mg of ethylene thiourea,
0.05 mg to 0.1 mg of sodium dodecyl sulfonate, and
0.05 g to 0.1 g of polyethylene glycol.

The present disclosure also provides a method for plating copper onto a surface of a substrate, comprising:
contacting a substrate with the copper plating solution as described above for copper plating.

In an embodiment, the method is a copper brush plating method.

In an embodiment, the method for plating copper onto a surface of a substrate is performed with one or more parameters selected from:
plating temperature ranging from 35° C. to 45° C.,
plating time ranging from 1 min to 2 min, and
operating voltage ranging from 2 V to 7 V.

In some embodiments, the method for plating copper onto a surface of a substrate is performed with the following parameters:
plating temperature ranging from 35° C. to 45° C.,
plating time ranging from 1 min to 2 min, and
operating voltage ranging from 2 V to 7 V.

Further disclosed herein is a copper brush plating method to provide coating on a surface of a substrate, comprising:
performing a copper plating treatment to a surface of a substrate by copper brushing plating, thereby forming a copper film on the surface of the substrate;
wherein an anode in the copper plating treatment is a brush plating roller; and
wherein the copper plating treatment further comprises:
   contacting the surface of the substrate with the copper plating solution as described above.

In an embodiment, the copper brushing plating is performed with one or more parameters selected from:
plating temperature ranging from 0° C. to 45° C.,
plating time ranging from 1 min to 10 min,
operating voltage ranging from 1 V to 7 V, and
moving speed of the plastic film relative to the brush plating roller ranging from 3 m/min to 10 m/min.

In some embodiments, the copper brushing plating is performed with the following parameters:
plating temperature ranging from 0° C. to 45° C.,
plating time ranging from 1 min to 10 min,
operating voltage ranging from 1 V to 7 V, and
moving speed of the plastic film relative to the brush plating roller ranging from 3 m/min to 10 m/min.

In an embodiment, the copper brush plating method further comprises:
performing a first copper plating treatment to a plastic film by physical vapor deposition, thereby forming a first copper film on a surface of the plastic film, and thereby forming the substrate.

In some embodiments, the copper plating solution of the copper plating treatment disclosed herein comprises: water, copper sulfate (CuSO₄), sulfuric acid, chloride ions, 1,4-cyclohexanedione monoethylene acetal, potassium phthalimide, and an amino polyol compound. In some embodiments, the mass ratio of 1,4-cyclohexanedione monoethylene acetal, potassium phthalimide, and the amino polyol compound is (0.6-1.0):(1.2-2.0):(1.8-3.0).

In an embodiment, the copper brush plating method comprises:
performing a first copper plating treatment to a plastic film by physical vapor deposition, thereby forming a first copper film on a surface of the plastic film, and thereby forming a substrate;
performing a second copper plating treatment to the coated surface of the substrate by copper brushing plating, thereby forming a third copper film on the first copper film of the substrate; and
wherein an anode in the second copper plating treatment is a brush plating roller; and
wherein the second copper plating treatment further comprises:
   contacting the first copper film of the substrate with a copper plating solution comprising a copper plating additive composition as described above.

In an embodiment, the copper plating solution of the second copper plating treatment comprises: water, copper sulfate (CuSO₄), sulfuric acid, chloride ions, 1,4-cyclohexanedione monoethylene acetal, potassium phthalimide, and an amino polyol compound. In some embodiments, the mass ratio of 1,4-cyclohexanedione monoethylene acetal, potassium phthalimide, and the amino polyol compound is (0.6-1.0):(1.2-2.0):(1.8-3.0).

In an embodiment, the copper brush plating method comprises:
performing a first copper plating treatment to a plastic film by physical vapor deposition, thereby forming a first copper film on a first surface of the plastic film and a second copper film on a second surface of the plastic film;
performing a second copper plating treatment to the first copper film and the second copper film by copper brush plating, thereby forming a third copper film on the first copper film, and forming a fourth copper film on the second copper film;
wherein an anode in the second copper plating treatment is a brush plating roller; and
wherein the second copper plating treatment further comprises:
   contacting the first copper film and the second copper film with a copper plating solution comprising a copper plating additive composition as described above.

In an embodiment, the copper plating solution of the second copper plating treatment comprises: water, copper sulfate (CuSO₄), sulfuric acid, chloride ions, 1,4-cyclohexanedione monoethylene acetal, potassium phthalimide, and an amino polyol compound. In some embodiments, the mass ratio of 1,4-cyclohexanedione monoethylene acetal, potassium phthalimide, and the amino polyol compound is (0.6-1.0):(1.2-2.0):(1.8-3.0).

In an embodiment, the plastic film is made of polypropylene (PP), polyethylene terephthalate (PET), polyethylene (PE), polyacrylonitrile (PAN), polyimide (PI), or polydimethylsiloxane (PDMS).

In an embodiment, the brush plating roller is covered by a spongy liquid absorption layer.

In an embodiment, a mass ratio of 1,4-cyclohexanedione monoethylene ketal, potassium phthalimide, and the amino polyol compound in the copper brush plating method is (0.6-1.0):(1.2-2.0):(1.8-3.0).

In an embodiment, the amino polyol compound in the copper brush plating method is 3-amino-1,2-propanediol.

In an embodiment, one liter of the copper plating solution for use in the copper brush plating method comprises:
water,
0.06 g to 0.10 g of 1,4-cyclohexanedione monoethylene ketal,
0.12 g to 0.20 g of potassium phthalimide,
0.18 g to 0.30 g of the polyol compound,
120 g to 220 g of copper sulfate,
50 g to 70 g of sulfuric acid, and
60 mg to 80 mg of chloride ions.

In an embodiment, the physical vapor deposition is magnetron sputtering or evaporation deposition.

In an embodiment, a sheet resistance of each of the first copper film and the second copper film is less than or equal to 2200 mΩ.

In an embodiment, the sheet resistances of the first copper film and the second copper film are independently ranging from 100 mΩ to 2200 mΩ.

In an embodiment, thicknesses of the first copper film and the second copper film are each independently ranging from 0.1 μm to 0.5 μm.

In an embodiment, the second copper plating treatment is performed with one or more parameters selected from:
plating temperature ranging from 0° C. to 45° C.,
plating time ranging from 1 min to 10 min,
operating voltage ranging from 1 V to 7 V, and
moving speed of the plastic film relative to the brush plating roller ranging from 3 m/min to 10 m/min.

In an embodiment, the second copper plating treatment is performed with the following parameters:
plating temperature ranging from 0° C. to 45° C.,
plating time ranging from 1 min to 10 min,
operating voltage ranging from 1 V to 7 V, and
moving speed of the plastic film relative to the brush plating roller ranging from 3 m/min to 10 m/min.

In an embodiment, a thickness of the plastic film ranges from 3.2 μm to 12 μm.

In an embodiment, the copper plating solution for use in the copper brush plating method further comprises one or more selected from a brightener, a surfactant, and a levelling agent.

In an embodiment, the brightener for use in the copper brush plating method is one or more selected from ethylene thiourea, benzimidazole, and fatty amine ethoxy sulfonate.

In an embodiment, the surfactant for use in the copper brush plating method is one or more selected from sodium dodecyl sulfonate, and bis (sodium sulfopropyl) disulfide.

In an embodiment, the levelling agent for use in the copper brush plating method is one or more selected from polyethylene glycol, 1,4-butynediol, and polyethyleneimine alkyl salt.

In an embodiment, one liter of the copper plating solution for use in the copper brush plating method comprises:
water,
0.06 g to 0.10 g of 1,4-cyclohexanedione monoethylene acetal,
0.12 g to 0.20 g of potassium phthalimide,
0.18 g to 0.30 g of the polyol compound,
150 g to 220 g of copper sulfate,
50 g to 70 g of sulfuric acid,
60 mg to 80 mg of chloride ions,
0.0002 mg to 0.0008 mg of a brightener,
0.05 mg to 0.1 mg of a surfactant, and
0.05 g to 0.1 g of a levelling agent.

### BRIEF DESCRIPTION OF THE DRAWINGS

In order to illustrate the embodiments of the present disclosure more clearly, the drawings are described below. They are provided for illustrative purposes only and are not intended to limit the scope of the present disclosure.

FIG. 1 is a flow chart of a copper brush plating method to provide coating on a surface of a plastic film according to one or more embodiments of the present disclosure.

FIG. 2 is a schematic view of a copper brush plating apparatus for use in the copper brush plating method according to one or more embodiments of the present disclosure.

FIG. 3 is a photograph showing a copper plating layer (a) in Example 1, a copper plating layer (b) in Example 2, and a copper plating layer (c) in Example 3 of the present disclosure.

### DETAILED DESCRIPTION

The present disclosure is described in detail with reference to the accompanying drawings and embodiments in order to make the objects, technical solutions, and advantages of the present disclosure be clear. It should be understood that the specific embodiments described herein are only for explaining the present disclosure, and not intended to limit the present disclosure.

Unless otherwise defined, all technical and scientific terms as used herein have the same meaning as those commonly understood by those skilled in the art of the present disclosure. Such terms, as used herein, are for the purpose of describing exemplary examples of, and without limiting, the present disclosure. The term “and/or” as used herein refers to any and all combinations of one or more items recited.

In the case of using “including”, “having”, and “comprising” as described herein, it is intended to cover the non-exclusive inclusion. Unless clear definitive terms such as “only”, “consisting . . . of”, etc., are used, another component can also be added.

In the description of the present disclosure, it should be understood that the terms “central”, “lateral”, “longitudinal”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise”, etc., indicate the orientations or positional relationships on the basis of the drawings. These terms are only for describing the present disclosure and simplifying the description, rather than indicating or implying that the related devices or elements must have the specific orientations, or be constructed or operated in the specific orientations, and therefore cannot be understood as limitations of the present disclosure.

When describing the position relationship, unless otherwise specified, when an element such as a layer, film or substrate is referred to as being “on” another film or layer, it can be directly on the other film or layer, or there can be one or more intermediate layers. Further, when a layer is referred to as “under” another layer, it can be directly under the other layer, or there can be one or more intermediate layers. It can be understood that when a layer is referred to as “between” two layers, it can be the only layer between the two layers, or there can be one or more intermediate layers.

When a numerical range is disclosed herein, the range is considered as being continuous and includes the minimum and maximum values of the range, as well as each value between the minimum and maximum values. Further, when the range is for integers, each integer between the minimum and maximum values of the range is included. In addition, when multiple ranges are provided to describe features or characteristics, the ranges can be combined. In other words, unless otherwise specified, all ranges disclosed herein shall be understood to include any and all sub-ranges included therein.

Unless specified to the contrary, the singular form of a term may include the plural form as well and cannot be understood as the number of the term is only one.

In addition, the drawings are not drawn at a scale of 1:1. The relative dimensions of the elements are drawn only by way of illustration to facilitate understanding of the present disclosure, but not necessarily in accordance with the actual scale. The scale in the drawings cannot be understood as a limitation of the present disclosure.

The present disclosure provides a copper plating additive composition that can increase the thickness, brightness, and whiteness of the plating layer.

The copper plating additive composition comprises: 1,4-cyclohexanedione monocthylene acctal, potassium phthalimide, and an amino polyol compound.

1,4-cyclohexanedione monoethylene acetal can improve the brightness of the copper brush plating layer. Potassium phthalimide can improve the dissolution efficiency of 1,4-cyclohexanedione monoethylene acetal, and at the same time plays the role of refining the grains, levelling, and improving the uniformity and thickness of the plating layer. The amino polyol compound can change the color tone of the copper layer, making it brighter. Moreover, the copper plating additive composition has the advantages of environmental friendliness, nontoxicity, low cost, etc., and is suitable for mass industrial production.

In an embodiment, a mass ratio of 1,4-cyclohexanedione monoethylene acetal, potassium phthalimide, and the amino polyol compound is (0.6-1.0): (1.2-2.0): (1.8-3.0), such as 0.6:1.2:1.8, 0.6:1.2:1.9, 0.6:1.2:2.0, 0.6:1.2:2.1, 0.6:1.2:2.2, 0.6:1.2:2.3, 0.6:1.2:2.4, 0.6:1.2:2.5, 0.6:1.2:2.6, 0.6:1.2:2.7, 0.6:1.2:2.8, 0.6:1.2:2.9, 0.6:1.2:3.0, 0.6:1.5:1.8, 0.6:1.5:1.9, 0.6:1.5:2.0, 0.6:1.5:2.1, 0.6:1.5:2.2, 0.6:1.5:2.3, 0.6:1.5:2.4, 0.6:1.5:2.5, 0.6:1.5:2.6, 0.6:1.5:2.7, 0.6:1.5:2.8, 0.6:1.5:2.9, 0.6:1.5:3.0, 0.6:1.8:1.8, 0.6:1.8:1.9, 0.6:1.8:2.0, 0.6:1.8:2.1, 0.6:1.8:2.2, 0.6:1.8:2.3, 0.6:1.8:2.4, 0.6:1.8:2.5, 0.6:1.8:2.6, 0.6:1.8:2.7, 0.6:1.8:2.8, 0.6:1.8:2.9, 0.6:1.8:3.0, 0.6:2.0:1.8, 0.6:2.0:1.9, 0.6:2.0:2.0, 0.6:2.0:2.1, 0.6:2.0:2.2, 0.6:2.0:2.3, 0.6:2.0:2.4, 0.6:2.0:2.5, 0.6:2.0:2.6, 0.6:2.0:2.7, 0.6:2.0:2.8, 0.6:2.0:2.9, 0.6:2.0:3.0, 0.8:1.2:1.8, 0.8:1.2:1.9, 0.8:1.2:2.0, 0.8:1.2:2.1, 0.8:1.2:2.2, 0.8:1.2:2.3, 0.8:1.2:2.4, 0.8:1.2:2.5, 0.8:1.2:2.6, 0.8:1.2:2.7, 0.8:1.2:2.8, 0.8:1.2:2.9, 0.8:1.2:3.0, 0.8:1.5:1.8, 0.8:1.5:1.9, 0.8:1.5:2.0, 0.8:1.5:2.1, 0.8:1.5:2.2, 0.8:1.5:2.3, 0.8:1.5:2.4, 0.8:1.5:2.5, 0.8:1.5:2.6, 0.8:1.5:2.7, 0.8:1.5:2.8, 0.8:1.5:2.9, 0.8:1.5:3.0, 0.8:1.8:1.8, 0.8:1.8:1.9, 0.8:1.8:2.0, 0.8:1.8:2.1, 0.8:1.8:2.2, 0.8:1.8:2.3, 0.8:1.8:2.4, 0.8:1.8:2.5, 0.8:1.8:2.6, 0.8:1.8:2.7, 0.8:1.8:2.8, 0.8:1.8:2.9, 0.8:1.8:3.0, 0.8:2.0:1.8, 0.8:2.0:1.9, 0.8:2.0:2.0, 0.8:2.0:2.1, 0.8:2.0:2.2, 0.8:2.0:2.3, 0.8:2.0:2.4, 0.8:2.0:2.5, 0.8:2.0:2.6, 0.8:2.0:2.7, 0.8:2.0:2.8, 0.8:2.0:2.9, 0.8:2.0:3.0, 1.0:1.5:1.8, 1.0:1.5:1.9, 1.0:1.5:2.0, 1.0:1.5:2.1, 1.0:1.5:2.2, 1.0:1.5:2.3, 1.0:1.5:2.4, 1.0:1.5:2.5, 1.0:1.5:2.6, 1.0:1.5:2.7, 1.0:1.5:2.8, 1.0:1.5:2.9, 1.0:1.5:3.0, 1.0:1.8:1.8, 1.0:1.8:1.9, 1.0:1.8:2.0, 1.0:1.8:2.1, 1.0:1.8:2.2, 1.0:1.8:2.3, 1.0:1.8:2.4, 1.0:1.8:2.5, 1.0:1.8:2.6, 1.0:1.8:2.7, 1.0:1.8:2.8, 1.0:1.8:2.9, 1.0:1.8:3.0, 1.0:2.0:1.8, 1.0:2.0:1.9, 1.0:2.0:2.0, 1.0:2.0:2.1, 1.0:2.0:2.2, 1.0:2.0:2.3, 1.0:2.0:2.4, 1.0:2.0:2.5, 1.0:2.0:2.6, 1.0:2.0:2.7, 1.0:2.0:2.8, 1.0:2.0:2.9, and 1.0:2.0:3.0.

In an embodiment, the mass ratio of 1,4-cyclohexanedione monoethylene acetal, potassium phthalimide, the amino polyol compound is (0.8-1.0): (1.5-2.0): (2.0-3.0).

In an embodiment, the mass ratio of 1,4-cyclohexanedione monoethylene acetal, potassium phthalimide, and the amino polyol compound is 1.0:2.0:3.0.

In an embodiment, the amino polyol compound is 3-amino-1,2-propanediol.

The present disclosure also provides a copper plating solution, comprising the copper plating additive composition as described above.

In an embodiment, the copper plating solution further comprises water, copper sulfate (CuSO₄), sulfuric acid, and chloride ions.

In an embodiment, the copper plating solution further comprises a brightener, a surfactant, and a levelling agent.

The copper plating additive composition as described above is added to the copper plating solution, and only a small amount thereof can greatly improve the thickness, brightness, and whiteness of the plating layer without changing the stability of the original copper plating solution and the performance of the original copper plating layer.

The present disclosure also provides a copper brush plating method to provide coating on a surface of a plastic film. The method has a high plating speed, thus can form a fine, continuous, and uniform copper film or layer without an adverse effect, and can provide good adhesion between plating films or layers. The sheet resistance of the plating film or layer formed by one-time brush plating can meet the requirement for the final product without punctured hole formed in the plastic film.

The present disclosure also provides a method for plating copper onto a surface of a substrate, comprising:
contacting a substrate with the copper plating solution as described above for copper plating.

The present disclosure also provides a copper brush plating method to provide coating on a surface of a substrate, comprising:
performing a copper plating treatment to a surface of a substrate by copper brushing plating, thereby forming a copper film on the surface of the substrate;
wherein an anode in the copper plating treatment is a brush plating roller; and
wherein the copper plating treatment further comprises:
   contacting the surface of the substrate with the copper plating solution as described above.

The copper brush plating method may further comprise:
performing a first copper plating treatment to a plastic film by physical vapor deposition, thereby forming a first copper film on a surface of the plastic film, and thereby forming the substrate.

In an embodiment, the substrate is made of plastic. Further, the substrate is a plastic film. In another embodiment, the substrate comprises a first copper film on a surface of the plastic film, in which the first copper film is formed by physical vapor deposition, such as magnetron sputtering or evaporation deposition.

In the process of copper plating, a motion speed of the substrate relative to the brush plating bath ranges, for example, from 3 m/min to 10 m/min.

In an embodiment, the copper brush plating method of the present disclosure comprises:
performing a first copper plating treatment to a plastic film by physical vapor deposition, thereby forming a first copper film on a surface of the plastic film, and thereby forming a substrate; and
performing a second copper plating treatment to the coated surface of the substrate by copper brushing plating, thereby forming a third copper film on the first copper film of the substrate;
wherein an anode in the second copper plating treatment is a brush plating roller; and
wherein the second copper plating treatment further comprises:
   contacting the first copper film of the substrate with a copper plating solution comprising a copper plating additive composition,
   wherein the copper plating additive composition comprises 1,4-cyclohexanedione monoethylene acetal, potassium phthalimide, and an amino polyol compound.

In an embodiment, the copper brush plating method comprises:
performing a first copper plating treatment to a plastic film by physical vapor deposition, thereby forming a first copper film on a first surface of the plastic film and a second copper film on a second surface of the plastic film;
performing a second copper plating treatment to the first copper film and the second copper film by copper brush plating, thereby forming a third copper film on the first copper film, and forming a fourth copper film on the second copper film;
wherein an anode in the second copper plating treatment is a brush plating roller; and
wherein the second copper plating treatment further comprises:
   contacting the first copper film and the second copper film with a copper plating solution comprising a copper plating additive composition,
   wherein the copper plating additive composition comprises 1,4-cyclohexanedione monoethylene acetal, potassium phthalimide, and an amino polyol compound.

The brush electroplating is also known as metal pen plating, rapid plating, or brush plating, which forms a metal coating by using an electrochemical method to discharge and crystallize metal ions on a surface of a cathode (workpiece) while using a plating pen impregnated with a plating solution as an anode. The present disclosure changes the brush plating pen into the anode brush plating roller, which can improve the plating speed, the production efficiency, the grain fineness, and/or the uniformity and continuity of the plating layer, and reduces the risk of perforation of the plastic film. In combination with using the copper plating solution containing 1,4-cyclohexanedione monocthylene acetal, potassium phthalimide, and the amino polyol compound, the method disclosed herein can refine the grains, improve the levelling and uniformity of the copper plating layer, and increase the thickness of the copper plating layer. In addition, the whiteness, brightness, and color tone of the copper plating layer can be improved. Further, the copper brush plating method has no adverse effect on the original copper plating film or layer formed by physical vapor deposition, and can provide good adhesion between the plating films or layers. The sheet resistance of the plating film or layer formed by one-time brush plating can meet the requirement for the final product. In addition, the copper plating solution used in the present disclosure has the advantages of environmental friendliness, nontoxicity, low cost, etc., and is suitable for large-scale industrial production.

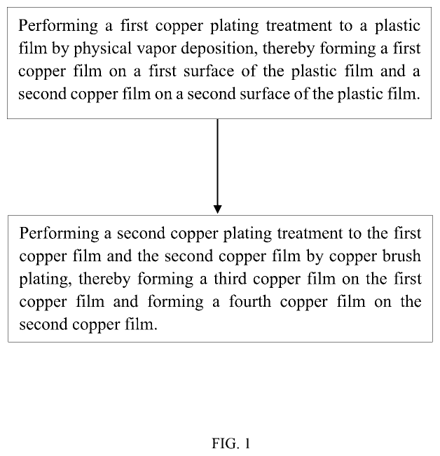

In an embodiment, the copper brush plating method includes steps S1 and S2, and the flow chart is shown in FIG. 1.

S1, performing a first copper plating treatment to a plastic film by physical vapor deposition, thereby forming a first copper film on a first surface of the plastic film and a second copper film on a second surface of the plastic film.

In an embodiment, the plastic film is made of polypropylene (PP), polyethylene terephthalate (PET), polyethylene (PE), polyacrylonitrile (PAN), polyimide (PI), or polydimethylsiloxane (PDMS).

In an embodiment, a thickness of the plastic film ranges from 3.2 μm to 12 μm.

In an embodiment, the physical vapor deposition is magnetron sputtering or evaporation deposition.

In an embodiment, both the first copper film and the second copper film are formed by magnetron sputtering.

In an embodiment, both the first copper film and the second copper film are formed by evaporation deposition.

In an embodiment, the magnetron sputtering includes the following steps: magnetron sputtering nickel-chromium, and magnetron sputtering copper.

In an embodiment, the evaporation deposition includes the following steps:

magnetron sputtering nickel-chromium, magnetron sputtering copper, and evaporation depositing copper.

In an embodiment, the sheet resistance of the first copper film is less than or equal to 2200 mΩ.

In an embodiment, the sheet resistance of the first copper film ranges from 100 m (2 to 2200 mΩ, such as 100 mΩ, 200 mΩ, 300 mΩ, 400 mΩ, 500 mΩ, 600 mΩ, 700 mΩ, 800 mΩ, 900 mΩ, 1000 mΩ, 1100 mΩ, 1200 mΩ, 1300 mΩ, 1400 mΩ, 1500 mΩ, 1600 mΩ, 1700 mΩ, 1800 mΩ, 1900 mΩ, 2000 mΩ, 2100 m22, or 2200 mΩ.

In an embodiment, the sheet resistance of the first copper film is less than or equal to 1500 mΩ.

In an embodiment, the sheet resistance of the first copper film is less than or equal to 500 mΩ.

In an embodiment, the thickness of the first copper film ranges from 0.1 μm to 0.5 μm, such as 0.1 μm, 0.15 μm, 0.2 μm, 0.25 μm, 0.3 μm, 0.35 μm, 0.4 μm, 0.45 μm, or 0.5μ m.

In an embodiment, the sheet resistance of the second copper film is less than or equal to 2200 mΩ.

In an embodiment, the sheet resistance of the second copper film ranges from 100 mΩ to 2200 mΩ, such as 100 mΩ, 200 mΩ, 300 mΩ, 400 mΩ, 500 mΩ, 600 mΩ, 700 mΩ, 800 mΩ, 900 mΩ, 1000 mΩ, 1100 mΩ, 1200 mΩ, 1300 mΩ, 1400 mΩ, 1500 mΩ, 1600 mΩ, 1700 mΩ, 1800 mΩ, 1900 mΩ, 2000 mΩ, 2100 mΩ, or 2200 mΩ.

In an embodiment, the sheet resistance of the second copper film is less than or equal to 1500 mΩ.

In an embodiment, the sheet resistance of the second copper film is less than or equal to 500 mΩ.

In an embodiment, the thickness of the second copper film ranges from 0.1 μm to 0.5 μm, such as 0.1 μm, 0.15 μm, 0.2 μm, 0.25 μm, 0.3 μm, 0.35 μm, 0.4 μm, 0.45μ, or 0.5 μm.

S2, performing a second copper plating treatment to the first copper film and the second copper film by copper brush plating, thereby forming a third copper film on the first copper film, and forming a fourth copper film on the second copper film.

In the present disclosure, the anode used in the second copper plating treatment is, for example, a brush plating roller. The changing of the brush plating pen into the anode brush plating roller can improve the plating speed, the production efficiency, the grain fineness, and/or the uniformity and continuity of the plating layer, and reduces the risk of perforation of the plastic film.

In an embodiment, the brush plating roller is covered by a spongy liquid absorption layer, which can eliminate the problem of copper plating on the brush plating roller and thus minimize the puncture of the copper film caused by the copper plating on the brush plating roller.

In an embodiment, a brush plating apparatus in the present disclosure includes an unwinding system, a brush plating system, a water washing system, a baking system, and a winding system.

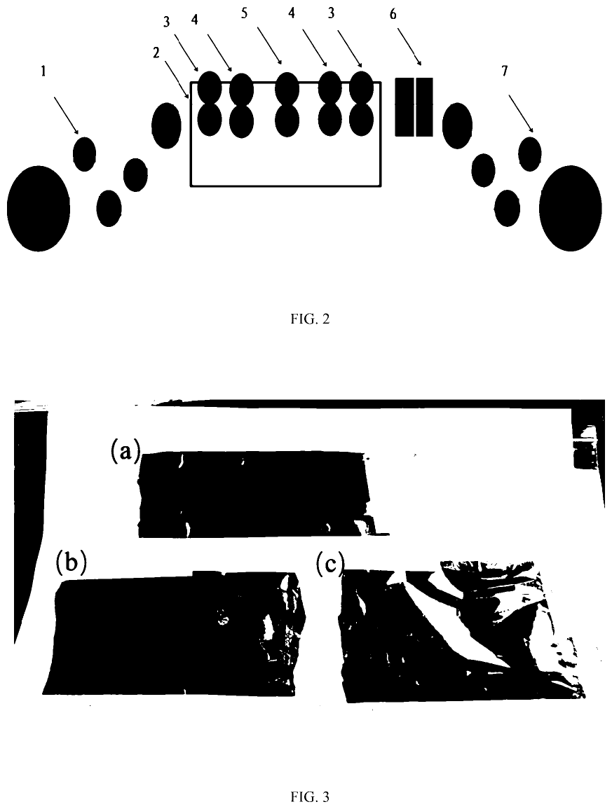

In an embodiment, the schematic view of the brush plating apparatus of the present disclosure can refer to FIG. 2, including an unwinding system 1, a brush plating bath 2, a water retaining roller 3, a cathode electrically conducting roller 4, an anode brush plating roller 5, a clip oven 6, and a winding system 7. Multiple water retaining rollers 3 can be arranged in the apparatus. 3 to 6 anode brush plating rollers 5 can be arranged in the middle, and the brush plating roller 5 can be covered by a spongy liquid absorption layer. In addition, an anti-oxidation system can be included in the brush plating system and the baking system to apply an anti-oxidation treatment to the copper plating layer, improving the anti-oxidation ability and prolonging the service life of the copper plating layer.

In the present disclosure, the copper plating solution used in the second copper plating treatment comprises water, copper sulfate, sulfuric acid, chloride ions, 1,4-cyclohexanedione monoethylene acetal, potassium phthalimide, and an amino polyol compound. Copper sulfate provides the basis for copper plating. Sulfuric acid is used to form an adsorption layer to slow down the displacing rate, inhibit the side reaction, and reduce the porosity of the copper layer in the displacement reaction, thereby improving the adhesion. Chloride ions provide the basis for preparing bright copper plating layer. In addition, chloride ions react with the monovalent copper ions to form CuCl precipitate, thus reducing the generation of “copper powder” of the plating layer, so that the plating layer is dense, fine, and not rough. 1,4-cyclohexanedione monoethylene acetal can improve the brightness of the copper brush plating layer. Potassium phthalimide can improve the dissolution efficiency of 1,4-cyclohexanedione monoethylene acetal, and at the same time plays the role of refining the grains, levelling, and improving the uniformity of the plating layer and increasing the thickness of the plating layer. The amino polyol compound can change the color tone of the copper layer, making it brighter.

In an embodiment, the second copper plating treatment is performed with following parameters:
plating temperature ranging from 0° C. to 45° C., plating time ranging from 1 min to 10 min, operating voltage ranging from 1 V to 7 V, and moving speed of the plastic film relative to the brush plating roller ranging from 3 m/min to 10 m/min.

It can be understood that the plating temperature can be, for example, 0° C., 2° C., 5° C., 8° C., 10° C., 12° C., 15° C., 18° C., 20° C., 21° C., 22° C., 23° C., 24° C., 25° C., 26° C., 27° C., 28° C., 29° C., 30° C., 31° C., 32° C., 33° C., 34° C., 35° C., 36° C., 37° C., 38° C., 39° C., 40° C., 41° C., 42° C., 43° C., 44° C., or 45° C. The plating time can be, for example, 1 min, 1.5 min, 2 min, 2.5 min, 3 min, 3.5 min, 4 min, 4.5 min, 5 min, 6 min, 6.5 min, 7 min, 7.5 min, 8 min, 8.5 min, 9 min, 9.5 min, or 10 min. The working voltage can be, for example, 1 V, 2 V, 3 V, 4 V, 5 V, 6 V, or 7 V. The moving speed of the plastic film relative to the brush plating roller can be, for example, 3 m/min, 3.5 m/min, 4 m/min, 4.5 m/min, 5 m/min, 5.5 m/min, 6 m/min, 6.5 m/min, 7 m/min, 7.5 m/min, 8 m/min, 8.5 m/min, 9 m/min, 9.5 m/min, or 10 m/min.

The present disclosure are further described in combination with the specific examples.

### Example 1

(1) In this example, 1 liter of an aqueous solution of the copper plating additive composition was prepared, which comprised:
10 g of 1,4-cyclohexanedione monoethylene acetal,
20 g of potassium phthalimide, and
30 g of 3-amino-1,2-propanediol.

(2) In this example, one liter of the copper plating solution was prepared, containing:
water,
0.10 g of 1,4-cyclohexanedione monoethylene acetal,
0.20 g of potassium phthalimide,
0.30 g of 3-amino-1,2-propanediol,
120 g of copper sulfate,
70 g of sulfuric acid,
70 mg of chloride ions,
0.0005 mg of ethylene thiourea,
0.08 mg of sodium dodecyl sulfonate, and
0.07 g of polyethylene glycol.

(3) The copper plating solution of this example was prepared according to a method comprising the following steps:
1) Preparation of 1,4-cyclohexanedione monoethylene acetal solution: 10 g of 1,4-cyclohexanedione monoethylene acetal was dissolved in 200 mL of deionized water, and stirred until the solution was clear.
2) Preparation of potassium phthalimide: 20 g of potassium phthalimide was weighed by using an analytical balance.
3) Preparation of 3-amino-1,2-propanediol solution: 30 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reached 1 L. The solution was continuously stirred to make the components evenly mixed together.
5) Copper sulfate, sulfuric acid, hydrogen chloride, ethylene thiourea, sodium dodecyl sulfonate, and polyethylene glycol were mixed in water, and then added with 10 ml of the copper plating additive composition prepared in step 4).

(4) Brush plating copper to provide coating on a surface of a PP film, the method comprises the following steps:

The copper brush plating on the PP film was performed for 5 minutes under the plating temperature of the plating solution of 40° C., the moving speed of the plastic film relative to the brush plating roller of 7 m/min, and the brush plating operating voltage of 2 V. Then the plating layer was slowly cleaned with flowing deionized water and blow-dried. The thickness of the copper plating layer was measured by using the Fischei test method, and the appearance of the copper plating layer was observed.

(5) As a comparative example, a copper brush plating step using a copper plating solution without the above-described copper plating additive composition was performed on a PP film under the same conditions of (4). The copper plating layer was cleaned and dried. The thickness of the copper plating layer was measured by using the Fischei test method, and the appearance of the copper plating layer was observed.

(6) Test result

Referring to FIG. 3, the copper plating layer (a) formed on the workpiece by brush plating with addition of the additive composition in this example has a thickness of 3.52 μm with a smooth surface and a bright copper color. In contrast, the copper plating layer formed on the workpiece by brush plating without addition of the additive composition in this example has a thickness of 1.06 μm with a rough surface and a dull pig liver color.

### Example 2

(1) 1 liter of an aqueous solution of the copper plating additive composition was prepared, comprising:
6 g of 1,4-cyclohexanedione monoethylene acetal,
12 g of potassium phthalimide, and
18 g of 3-amino-1,2-propanediol.

(2) In this example, one liter of the copper plating solution was prepared, containing:
water,
0.06 g of 1,4-cyclohexanedione monoethylene acetal,
0.12 g of potassium phthalimide,
0.18 g of 3-amino-1,2-propanediol,
150 g of copper sulfate,
60 g of sulfuric acid,
70 mg of chloride ions,
0.0005 mg of ethylene thiourea,
0.08 mg of sodium dodecyl sulfonate, and
0.07 g of polyethylene glycol.

(3) The copper plating solution of this example was prepared according to a method comprising following steps:
1) Preparation of 1,4-cyclohexanedione monoethylene acetal solution: 6 g of 1,4-cyclohexanedione monoethylene acetal was dissolved in 200 mL of deionized water, and stirred until the solution was clear.
2) Preparation of potassium phthalimide: 12 g of potassium phthalimide was weighed by using an analytical balance.
3) Preparation of 3-amino-1,2-propanediol 18 g solution: of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, hydrogen chloride, ethylene thiourea, sodium dodecyl sulfonate, and polyethylene glycol were mixed in water, and then added with 10 mL of the copper plating additive composition prepared in step 4).

(4) Brush plating copper to provide coating on a surface of a PP film, the method comprises the following steps:

The copper brush plating on the PP film was performed for 5 minutes under the plating temperature of the plating solution of 40° C., the moving speed of the plastic film relative to the brush plating roller of 7 m/min, and the brush plating operating voltage of 2 V. Then the plating layer was slowly cleaned with flowing deionized water and blow-dried. The thickness of the copper plating layer was measured by using the Fischei test method, and the appearance of the copper plating layer was observed.

(5) As a comparative example, a copper brush plating step using a copper plating solution without the above-described copper plating additive composition was performed on a PP film under the same conditions of (4). The copper plating layer was cleaned and dried. The thickness of the copper plating layer was measured by using the Fischei test method, and the appearance of the copper plating layer was observed.

(6) Test result

Referring to FIG. 3, the copper plating layer (b) formed on the workpiece by brush plating with addition of the additive composition in this example has a thickness of 3.14 μm with a smooth surface and a bright copper color. In contrast, the copper plating layer formed on the workpiece by brush plating without addition of the additive composition in this example has a thickness of 0.98 μm with a rough surface and a dull pig liver color.

### Example 3

(1) 1 liter of an aqueous solution of the copper plating additive composition was prepared, comprising:
7 g of 1,4-cyclohexanedione monoethylene acetal,
14 g of potassium phthalimide, and
21 g of 3-amino-1,2-propanediol.

(2) In this example, one liter of the copper plating solution was prepared, containing:
water,
0.07 g of 1,4-cyclohexanedione monoethylene acetal,
0.14 g of potassium phthalimide,
0.21 g of 3-amino-1,2-propanediol,
180 g of copper sulfate,
50 g of sulfuric acid,
60 mg of chloride ions,
0.0002 mg of ethylene thiourea,
0.05 mg of sodium dodecyl sulfonate, and
0.05 g of polyethylene glycol.

(3) The copper plating solution of this example was prepared according to a method comprising following steps:
1) Preparation of 1,4-cyclohexanedione monoethylene acetal solution: 7 g of 1,4-cyclohexanedione monoethylene acetal was dissolved in 200 mL of deionized water, and stirred until the solution was clear.
2) Preparation of potassium phthalimide: 14 g of potassium phthalimide was weighed by using an analytical balance.
3) Preparation of 3-amino-1,2-propanediol solution: 21 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, hydrogen chloride, ethylene thiourea, sodium dodecyl sulfonate, and polyethylene glycol were mixed in water, and then added with 10 mL of the copper plating additive composition prepared in step 4).

(4) Brush plating copper to provide coating on a surface of a PP film, the method comprises the following steps:

The copper brush plating on the PP film was performed for 5 minutes under the plating temperature of the plating solution of 40° C., the moving speed of the plastic film relative to the brush plating roller of 7 m/min, and the brush plating operating voltage of 2 V. Then the plating layer was slowly cleaned with flowing deionized water and blow-dried. The thickness of the copper plating layer was measured by using the Fischei test method, and the appearance of the copper plating layer was observed.

(5) As a comparative example, a copper brush plating step using a copper plating solution without the above-described copper plating additive composition was performed on a PP film under the same conditions of (4). The copper plating layer was cleaned and dried. The thickness of the copper plating layer was measured by using the Fischei test method, and the appearance of the copper plating layer was observed.

(6) Test result

Referring to FIG. 3, the copper plating layer (c) formed on the workpiece by brush plating with addition of the additive composition in this example has a thickness of 3.21 μm with a smooth surface and a bright copper color. In contrast, the copper plating layer formed on the workpiece by brush plating without addition of the additive composition in this example has a thickness of 1.05 μm with a rough surface and a dull pig liver color.

### Example 4

(1) 1 liter of an aqueous solution of the copper plating additive composition was prepared, comprising:
8 g of 1,4-cyclohexanedione monoethylene acetal,
16 g of potassium phthalimide, and
24 g of 3-amino-1,2-propanediol.

(2) In this example, one liter of the copper plating solution was prepared, containing:
water,
0.08 g of 1,4-cyclohexanedione monoethylene acetal,
0.16 g of potassium phthalimide,
0.24 g of 3-amino-1,2-propanediol,
200 g of copper sulfate,
70 g of sulfuric acid,
80 mg of chloride ions,
0.0008 mg of ethylene thiourea,
0.1 mg of sodium dodecyl sulfonate, and
0.05 g of polyethylene glycol.

(3) The copper plating solution of this example was prepared according to a method comprising following steps:
1) Preparation of 1,4-cyclohexanedione monoethylene acetal solution: 8 g of 1,4-cyclohexanedione monoethylene acetal was dissolved in 200 mL of deionized water, and stirred until the solution was clear.
2) Preparation of potassium phthalimide: 16 g of potassium phthalimide was weighed by using an analytical balance.
3) Preparation of 3-amino-1,2-propanediol solution: 24 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, hydrogen chloride, ethylene thiourea, sodium dodecyl sulfonate, and polyethylene glycol were mixed in water, and then added with 10 mL of the copper plating additive composition prepared in step 4).

(4) Brush plating copper to provide coating on a surface of a PP film, the method comprises the following steps:

The copper brush plating on the PP film was performed for 5 minutes under the plating temperature of the plating solution of 40° C., the moving speed of the plastic film relative to the brush plating roller of 7 m/min, and the brush plating operating voltage of 2 V. Then the plating layer was slowly cleaned with flowing deionized water and blow-dried. The thickness of the copper plating layer was measured by using the Fischei test method, and the appearance of the copper plating layer was observed.

(5) As a comparative example, a copper brush plating step using a copper plating solution without the above-described copper plating additive composition was performed on a PP film under the same conditions of (4). The copper plating layer was cleaned and dried. The thickness of the copper plating layer was measured by using the Fischei test method, and the appearance of the copper plating layer was observed.

(6) Test result

The copper plating layer formed on the workpiece by brush plating with addition of the additive composition in this example has a thickness of 3.31 μm with a smooth surface and a bright copper color. In contrast, the copper plating layer formed on the workpiece by brush plating without addition of the additive composition in this example has a thickness of 1.02 μm with a rough surface and a dull pig liver color.

### Example 5

(1) 1 liter of an aqueous solution of the copper plating additive composition was prepared, comprising:
9 g of 1,4-cyclohexanedione monoethylene acetal,
18 g of potassium phthalimide, and
27 g of 3-amino-1,2-propanediol.

(2) In this example, one liter of the copper plating solution was prepared, containing:
water,
0.09 g of 1,4-cyclohexanedione monoethylene acetal,
0.18 g of potassium phthalimide,
0.27 g of 3-amino-1,2-propanediol,
220 g of copper sulfate,
70 g of sulfuric acid,
60 mg of chloride ions,
0.0008 mg of ethylene thiourea,
0.1 mg of sodium dodecyl sulfonate, and
0.06 g of polyethylene glycol.

(3) The copper plating solution of this example was prepared according to a method comprising following steps:
1) Preparation of 1,4-cyclohexanedione monoethylene acetal solution: 9 g of 1,4-cyclohexanedione monoethylene acetal was dissolved in 200 mL of deionized water, and stirred until the solution was clear.
2) Preparation of potassium phthalimide: 18 g of potassium phthalimide was weighed by using an analytical balance.
3) Preparation of 3-amino-1,2-propanediol solution: 27 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monocthylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, hydrogen chloride, ethylene thiourea, sodium dodecyl sulfonate, and polyethylene glycol were mixed in water, and then added with 10 mL of the copper plating additive composition prepared in step 4).

(4) Brush plating copper to provide coating on a surface of a PP film, the method comprises the following steps:

The copper brush plating on the PP film was performed for 5 minutes under the plating temperature of the plating solution of 40° C., the moving speed of the plastic film relative to the brush plating roller of 7 m/min, and the brush plating operating voltage of 2 V. Then the plating layer was slowly cleaned with flowing deionized water and blow-dried. The thickness of the copper plating layer was measured by using the Fischei test method, and the appearance of the copper plating layer was observed.

(5) As a comparative example, a copper brush plating step using a copper plating solution without the above-described copper plating additive composition was performed on a PP film under the same conditions of (4). The copper plating layer was cleaned and dried. The thickness of the copper plating layer was measured by using the Fischei test method, and the appearance of the copper plating layer was observed.

(6) Test result

The copper plating layer formed on the workpiece by brush plating with addition of the additive composition in this example has a thickness of 3.36 μm with a smooth surface and a bright copper color. In contrast, the copper plating layer formed on the workpiece by brush plating without addition of the additive composition in this example has a thickness of 1.34 μm with a rough surface and a dull pig liver color.

The above examples show that the present disclosure has no adverse effect on the original performance of the high-speed brush copper plating solution, and has technical effects on improving the adhesion of the plating layer, refining the grains, avoiding the perforation of the plating layer, etc. A continuous and uniform copper plating layer with refined grains can be obtained, which can fully meet the needs of large-scale industrial production.

### Example 6

This example provides a copper plating method on a PP film, including the following steps:

(1) Preparation of the copper plating solution. In this example, one liter of the copper plating solution was prepared, containing:
water,
0.1 g of 1,4-cyclohexanedione monoethylene acetal,
0.2 g of potassium phthalimide,
0.3 g of 3-amino-1,2-propanediol,
220 g of copper sulfate,
60 g of sulfuric acid, and
70 mg of chloride ions.

The copper plating solution of this example was prepared according to a method comprising following steps:
1) Preparation of 1,4-cyclohexanedione monoethylene acetal solution: 10 g of 1,4-cyclohexanedione monoethylene acetal was dissolved in 200 ml of deionized water, stirred until the solution was clear.
2) Preparation of potassium phthalimide: 20 g of potassium phthalimide was weighed by using an analytical balance.
3) Preparation of 3-amino-1,2-propanediol solution: 30 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, and hydrogen chloride were mixed in water, and then added with 10 mL of the copper plating additive composition prepared in step 4).

(2) The PP film was subjected to magnetron sputtering in an order of first magnetron sputtering nickel-chromium, and then magnetron sputtering copper (first copper plating treatment). The formed copper film was tested as follows: I) The sheet resistance of the copper film was tested by sampling two points on the film. The test result of the first point was 131 mΩ, and the test result of the second point was 207 mΩ. II) An adhesive tape was adhered to the copper film and then torn off by hand, and sporadic copper scraps were peeled off at the end of the film. III) Tiny pores were observed in the copper film by mobile phone lightening from the back of the film. IV) The thickness of the copper film as measured by the Fischei test method was 0.237 μm.

(3) The copper film was subjected to the second copper plating treatment adopting the copper brush plating:

The brush plating apparatus as shown in FIG. 2 was used, and the copper film was subjected to the second copper plating treatment with following parameters: The plating temperature was 30° C., the plating time was 1 min, the operating voltage was 1 V, and the moving speed of the plastic film relative to the brush plating roller was 5 m/min. The formed copper film was tested as follows: I) The sheet resistance of the copper film was tested by sampling two points on the film. The test result of the first point was 3.6 mΩ, and the test result of the second point was 3.26 mΩ. II) An adhesive tape was adhered to the copper film and then torn off by hand, and no copper was peeled off. Thus, the copper film passed the adhesion test. III) The brush plating copper film was bright, and no other pore was observed except the pores formed in the sheet resistance test. IV) The thickness of the copper film as measured by the Fischei test method was 1.995 μm, indicating that the film thickness increased by brush plating was 1.758 μm.

### Example 7

This example provides a copper plating method on a PP film, including the following steps:

(1) Preparation of the copper plating solution. In this example, one liter of the copper plating solution was prepared, containing:
water,
0.6 g of 1,4-cyclohexanedione monoethylene acetal,
0.12 g of potassium phthalimide,
0.18 g of 3-amino-1,2-propanediol,
220 g of copper sulfate,
60 g of sulfuric acid, and
70 mg of chloride ions.

The copper plating solution of this example was prepared according to a method comprising following steps:
1) Preparation of 1,4-cyclohexanedione monoethylene acetal solution: 10 g of 1,4-cyclohexanedione monoethylene acetal was dissolved in 200 ml of deionized water, stirred until the solution was clear.
2) Preparation of potassium phthalimide: 20 g of potassium phthalimide was weighed by using an analytical balance.
3) Preparation of 3-amino-1,2-propanediol solution: 30 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, and hydrogen chloride were mixed in water, and then added with 10 mL of the copper plating additive composition prepared in step 4).

(2) The PP film was subjected to magnetron sputtering in an order of first magnetron sputtering nickel-chromium, and then magnetron sputtering copper (first copper plating treatment). The formed copper film was tested as follows: I) The sheet resistance of the copper film was tested, and the test result was 388 m (2. II) An adhesive tape was adhered to the copper film and then torn off by hand, and the result showed qualified adhesion. III) Tiny pores were observed in the copper film by mobile phone lightening from the back of the film. IV) The thickness of the copper film as measured by the Fischei test method was 0.357 μm.

(3) The copper film was subjected to the second copper plating treatment adopting the copper brush plating:

The brush plating apparatus as shown in FIG. 2 was used, and the copper film was subjected to the second copper plating treatment with following parameters: The plating temperature was 30° C., the plating time was 2 min, the operating voltage was 1 V, and the moving speed of the plastic film relative to the brush plating roller was 5 m/min. The formed copper film was tested as follows: I) The sheet resistance of the copper film was tested, and the test result was 7.66 msΩ. II) An adhesive tape was adhered to the copper film and then torn off by hand, and no copper was peeled off. Thus, the copper film passed the adhesion test. III) The brush plating copper film was bright, and no other pore was observed except the pores formed in the sheet resistance test. IV) The thickness of the copper film as measured by the Fischei test method was 0.913 μm, indicating that the film thickness increased by brush plating was 0.556 μm.

### Example 8

This example provides a copper plating method on a PP film, including the following steps:

(1) Preparation of the copper plating solution. In this example, one liter of the copper plating solution was prepared, containing:
water,
0.7 g of 1,4-cyclohexanedione monoethylene acetal,
0.14 g of potassium phthalimide,
0.21 g of 3-amino-1,2-propanediol,
220 g of copper sulfate,
60 g of sulfuric acid, and
70 mg of chloride ions.

The copper plating solution of this example was prepared according to a method comprising following steps:
1) Preparation of 1,4-cyclohexanedione monoethylene acetal solution: 10 g of 1,4-cyclohexanedione monoethylene acetal was dissolved in 200 ml of deionized water, stirred until the solution was clear.
2) Preparation of potassium phthalimide: 20 g of potassium phthalimide was weighed by using an analytical balance.
3) Preparation of 3-amino-1,2-propanediol solution: 30 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monoethylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, and hydrogen chloride were mixed in water, and then added with 10 mL of the copper plating additive composition prepared in step 4).

(2) The PP film was subjected to magnetron sputtering in an order of first magnetron sputtering nickel-chromium, and then magnetron sputtering copper (first copper plating treatment). The formed copper film was tested as follows: I) The sheet resistance of the copper film was tested, and the test result was 121 mΩ. II) An adhesive tape was adhered to the copper film and then torn off by hand, and the result showed qualified adhesion. III) Tiny pores were observed in the copper film by mobile phone lightening from the back of the film. IV) The thickness of the copper film as measured by the Fischei test method was 0.371 μm.

(3) The copper film was subjected to the second copper plating treatment adopting the copper brush plating:

The brush plating apparatus as shown in FIG. 2 was used, and the copper film was subjected to the second copper plating treatment with following parameters: The plating temperature was 30° C., the plating time was 3 min, the operating voltage was 1 V, and the moving speed of the plastic film relative to the brush plating roller was 5 m/min. The formed copper film was tested as follows: I) The sheet resistance of the copper film was tested, and the test result was 5.21 mΩ. II) An adhesive tape was adhered to the copper film and then torn off by hand, and no copper was peeled off. Thus, the copper film passed the adhesion test. III) The brush plating copper film was bright, and no other pore was observed except the pores formed in the sheet resistance test. IV) The thickness of the copper film as measured by the Fischei test method was 0.875 μm, indicating that the film thickness increased by brush plating was 0.504 μm.

### Example 9

This example provides a copper plating method on a PET film, including the following steps:

(1) Preparation of the copper plating solution. In this example, one liter of the copper plating solution was prepared, containing:
water,
0.06 g of 1,4-cyclohexanedione monoethylene acetal,
0.12 g of potassium phthalimide,
0.25 g of 3-amino-1,2-propanediol,
200 g of copper sulfate,
60 g of sulfuric acid,
70 mg of chloride ions,
0.0002 mg of ethylene thiourea,
0.05 mg of sodium dodecyl sulfonate, and
0.05 g of polyethyleneimine alkyl salt.

The copper plating solution of this example was prepared according to a method comprising following steps:
1) Preparation of 1,4-cyclohexanedione monoethylene acetal solution: 6 g of 1,4-cyclohexanedione monoethylene acetal was dissolved in 200 ml of deionized water, stirred until the solution was clear.
2) Preparation of potassium phthalimide: 12 g of potassium phthalimide was weighed by using an analytical balance.
3) Preparation of 3-amino-1,2-propanediol solution: 25 g of 3-amino-1,2-propanediol was dissolved in 500 mL of deionized water, and stirred until the solution was clear.
4) Preparation of the copper plating additive composition: Potassium phthalimide weighed in step 2) was slowly added into the 1,4-cyclohexanedione monocthylene acetal solution prepared in step 1), fully stirred and dissolved to mix them well. Then the solution was slowly added into the 3-amino-1,2-propanediol solution prepared in step 3), followed by adding deionized water until the total volume reaches 1 L. The solution was continuously stirred to make the components evenly mixed together.
5) Copper sulfate, sulfuric acid, hydrogen chloride, ethylene thiourea, sodium dodecyl sulfonate, and polyethyleneimine alkyl salt were mixed in water, and then added with 10 mL of the copper plating additive composition prepared in step 4).

(2) The PET film was subjected to magnetron sputtering in an order of first magnetron sputtering nickel-chromium, and then magnetron sputtering copper (first copper plating treatment). The formed copper film was tested as follows: I) The sheet resistance of the copper film was tested, and the test result was 400 mΩ. II) An adhesive tape was adhered to the copper film and then torn off by hand, and the result showed qualified adhesion. III) Tiny pores were observed in the copper film by mobile phone lightening from the back of the film. IV) The thickness of the copper film as measured by the Fischei test method was 0.34 μm.

(3) The first copper film and the second copper film were subjected to the second copper plating treatment adopting the copper brush plating:

The brush plating apparatus as shown in FIG. 2 was used, and the copper film was subjected to the second copper plating treatment with following parameters: The plating temperature is 30° C., the plating time is 3 min, the operating voltage is 5 V, and the moving speed of the plastic film relative to the brush plating roller is 7 m/min. The formed copper film was tested as follows: I) The sheet resistance of the copper film was tested, and the test result was 5.12 mΩ. II) An adhesive tape was adhered to the copper film and then torn off by hand, and no copper was peeled off. Thus, the copper film passed the adhesion test. III) The brush plating copper film was bright, and no other pore was observed except the pores formed in the sheet resistance test. IV) The thickness of the copper film as measured by the Fischei test method was 0.885 μm, indicating that the film thickness increased by brush plating was 0.545 μm.

The technical features of the above-mentioned embodiments can be combined arbitrarily. In order to make the description concise, not all possible combinations of the technical features are described in the embodiments. However, as long as there is no contradiction in the combination of these technical features, the combinations should be considered as in the scope of the present disclosure.

The above-described embodiments are only several implementations of the present disclosure, and the descriptions are relatively specific and detailed, but they should not be construed as limiting the scope of the present disclosure. It should be understood by those of ordinary skill in the art that various modifications and improvements can be made without departing from the concept of the present disclosure, and all fall within the protection scope of the present disclosure. Therefore, the patent protection of the present disclosure shall be defined by the appended claims.

1. A copper plating additive composition, comprising:
1,4-cyclohexanedione monoethylene acetal, potassium phthalimide, and an amino polyol compound.

2. The copper plating additive composition of claim 1, wherein a mass ratio of 1,4-cyclohexanedione monoethylene acetal, potassium phthalimide, and the amino polyol compound is (0.6-1.0):(1.2-2.0):(1.8-3.0).

3. The copper plating additive composition of claim 1, wherein the mass ratio of 1,4-cyclohexanedione monoethylene acetal, potassium phthalimide, the amino polyol compound is (0.8-1.0):(1.5-2.0):(2.0-3.0).

4. The copper plating additive composition of claim 1, wherein the amino polyol compound is 3-amino-1,2-propanediol.

5. A copper plating solution, comprising the copper plating additive composition of claim 1.

6. The copper plating solution of claim 5, further comprising water, copper sulfate, sulfuric acid, and chloride ions.

7. The copper plating solution of claim 5, wherein one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid, and
60 mg to 80 mg of chloride ions.

8. The copper plating solution of claim 5, further comprising a brightener, a surfactant, and a levelling agent,
wherein
the brightener is one or more selected from ethylene thiourea, benzimidazole, and fatty amine ethoxy sulfonate,
the surfactant is one or more selected from sodium dodecyl sulfonate, and bis (sodium sulfopropyl) disulfide,
the surfactant is one or more selected from sodium dodecyl sulfonate, and bis (sodium sulfopropyl) disulfide, or
the levelling agent is one or more selected from polyethylene glycol, 1,4-butynediol, and polyethyleneimine alkyl salt.

9.-11. (canceled)

12. The copper plating solution of claim 8, wherein one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid,
60 mg to 80 mg of chloride ions,
0.0002 mg to 0.0008 mg of the brightener,
0.05 mg to 0.1 mg of the surfactant, and
0.05 g to 0.1 g of the levelling agent.

13. The copper plating solution of claim 8, wherein one liter of the copper plating solution comprises:
water,
0.06 g to 0.10 g of 1,4-cyclohexanedione monoethylene acetal,
0.12 g to 0.20 g of potassium phthalimide,
0.18 g to 0.30 g of the amino polyol compound,
120 g to 220 g of copper sulfate,
50 g to 70 g of sulfuric acid,
60 mg to 80 mg of chloride ions,
0.0002 mg to 0.0008 mg of ethylene thiourea,
0.05 mg to 0.1 mg of sodium dodecyl sulfonate, and
0.05 g to 0.1 g of polyethylene glycol.

14. A method for plating copper onto a surface of a substrate, comprising:
contacting a substrate with a copper plating solution of claim 5 for copper plating.

15. The plating method of claim 14, wherein the method is performed with one or more parameters selected from:
plating temperature ranging from 35° C. to 45° C.,
plating time ranging from 1 min to 2 min, and
operating voltage ranging from 2 V to 7 V.

16. A copper brush plating method to provide coating on a surface of a substrate, comprising:
performing a copper plating treatment to a surface of a substrate by copper brushing plating, thereby forming a copper film on the surface of the substrate;
wherein an anode in the copper plating treatment is a brush plating roller; and
wherein the copper plating treatment further comprises:
contacting the surface of the substrate with a copper plating solution according to claim 5.

17. The copper brush plating method of claim 16, further comprises:
performing a first copper plating treatment to a plastic film by physical vapor deposition, thereby forming a first copper film on a surface of the plastic film, and thereby forming the substrate.

18. A copper brush plating method to provide coating on a surface of a substrate, comprising:
performing a first copper plating treatment to a plastic film by physical vapor deposition, thereby forming a first copper film on a first surface of the plastic film and a second copper film on a second surface of the plastic film;
performing a second copper plating treatment to the first copper film and the second copper film by copper brush plating, thereby forming a third copper film on the first copper film, and forming a fourth copper film on the second copper film;
wherein an anode in the second copper plating treatment is a brush plating roller; and
wherein the second copper plating treatment further comprises:
contacting the first copper film and the second copper film with a copper plating solution comprising a copper plating additive composition according to claim 5.

19. The copper brush plating method of claim 18,
wherein a sheet resistance of each of the first copper film and the second copper film is less than or equal to 2200 mΩ, and/or
wherein a thicknesses of the first copper film and the second copper film are each independently ranging from 0.1 μm to 0.5 μm.

20. The copper brush plating method of claim 18, wherein the second copper plating treatment is performed with one or more parameters selected from:
plating temperature ranging from 0° C. to 45° C.,
plating time ranging from 1 min to 10 min,
operating voltage ranging from 1 V to 7 V, and
moving speed of the plastic film relative to the brush plating roller ranging from 3 m/min to 10 m/min.

21. The copper brush plating method of claim 17, wherein a thickness of the plastic film ranges from 3.2 μm to 12 μm.

22. The copper brush plating method of claim 17, wherein the physical vapor deposition is magnetron sputtering or evaporation deposition.

23. The copper brush plating method of claim 16, wherein the brush plating roller is covered by a spongy liquid absorption layer.
